(19) United States
(12) Patent Application Publication
(10) Pub. No.: US 2020/0035158 A1
(43) Pub. Date: Jan. 30, 2020

(54) PIXEL DRIVING CIRCUIT, METHOD FOR DRIVING THE SAME AND DISPLAY DEVICE

(71) Applicant: BOE TECHNOLOGY GROUP CO., LTD., Beijing (CN)

(72) Inventors: Shengji YANG, Beijing (CN); Xue DONG, Beijing (CN); Jing LV, Beijing (CN); Xiaochuan CHEN, Beijing (CN); Dongni LIU, Beijing (CN); Pengcheng LU, Beijing (CN); Lei WANG, Beijing (CN); Jie FU, Beijing (CN); Han YUE, Beijing (CN); Li XIAO, Beijing (CN)

(73) Assignee: BOE TECHNOLOGY GROUP CO., LTD., Beijing (CN)

(21) Appl. No.: 15/735,793

(22) PCT Filed: Jun. 21, 2017
(86) PCT No.: PCT/CN2017/089300

§ 371 Date: Dec. 12, 2017

(30) Foreign Application Priority Data
Oct. 28, 2016 (CN) 201610960369.6

(51) Int. Cl. G09G 3/3258; G09G 3/3283; H01L 27/32

(52) U.S. Cl. CPC G09G 3/3258; H01L 27/3244; G09G 3/3283

(57) ABSTRACT

A pixel driving circuit, a method for driving the same and a display device are provided. The pixel driving circuit includes a driving transistor, a reset control unit, a charging-discharging unit, a compensation control unit and a light-emission control unit, the reset control unit is connected to a reset control signal output end, an initial signal output end and a control node respectively, a gate electrode of the driving transistor is connected to the control node, the compensation control unit is connected to a compensation control signal output end, the light-emission control unit is connected to a high level output end, a main light-emission control line, a first electrode of the driving transistor, a second electrode of the driving transistor, N secondary light-emission control lines and N light-emission elements respectively.

### CROSS-REFERENCE TO RELATED APPLICATION

This application claims priority to Chinese Patent Application No. 201610960369.6 filed Oct. 28, 2016, the disclosures of which are incorporated in their entirety by reference herein.

### TECHNICAL FIELD

The present disclosure relates to the field of pixel driving technology, and in particularly to a pixel driving circuit, a method for driving the same and a display device.

### BACKGROUND

An active organic light emitting diode panel (AMOLED) is one of hot spots of current research filed of flat panel display, as compared with a liquid crystal display, an organic light emitting diode (OLED) has advantages of low energy consumption, low manufacturing cost, self-light emitting, wide viewing angle and quick response speed and the like. Currently, the OLEDs are starting to replace conventional liquid crystal displays (LCDs) in fields of display, such as mobile phones, personal digital assistants (PDAs), digital camera, and a design of pixel driving circuit is a kernel content of AMOLED display and has important research significance.

In an OLED display in the related art, a size of a pixel per inch (PPI, a quantity of pixels per inch) of OLED is mainly controlled by a process and a size of a fine metal mask (FMM), that is, under the premise that a level of the process reaches a certain degree, a size of an aperture of the FMM decides the size of the PPI of the OLED. However, in the present age of rising of AR/VR consumer electronics, components of higher PPI need to be designed to improve sensory effects, while a conventional pixel compensation driving circuit is unable to correspond to such a pixel arrangement.

Specifically, in an AMOLED panel in the related art, each pixel has a pixel compensation driving circuit to realize a light-emission of OLED, which limits the size of PPI of pixels of the back board greatly.

### SUMMARY

An object of the present disclosure is to provide a pixel driving circuit and a method for driving the same and a display device to solve the problem in the related art where a design of the pixel driving circuit limits the size of PPI of pixels of the back board.

In order to realize the above object, in one aspect, the present disclosure provides a pixel driving circuit, including a driving transistor, a reset control unit, a charging-discharging unit, a compensation control unit and a light-emission control unit, where the reset control unit is connected to a reset control signal output end, an initial signal output end and a control node; a gate electrode of the driving transistor is connected to the control node, a first electrode of the driving transistor is connected to a data line via the compensation control unit, and a second electrode of the driving transistor is connected to a first end of the charging-discharging unit via the compensation control unit; a second end of the charging-discharging unit is connected to a voltage output end; the compensation control unit is connected to a compensation control signal output end, and is configured to control, in a compensating period, in response to a compensation control signal outputted by the compensation control signal output end, the first electrode of the driving transistor to receive a data voltage on the data line and control the control node to be conducted to the second electrode of the driving transistor; and the light-emission control unit is connected to a high level output end, a main light-emission control line, the first electrode of the driving transistor, the second electrode of the driving transistor, N secondary light-emission control lines and N light-emission elements respectively, and is configured to control, in a light-emission period, in response to a main light-emission control signal outputted by the main light-emission control line, the first electrode of the driving transistor to connect to the high level output end, to turn on the driving transistor, and control, in response to secondary light-emission control signals outputted by the N secondary light-emission control lines respectively, the N light-emission elements to connect to the second electrode of the driving transistor in a time-division manner, where N is an integer greater than 1, and n is a positive integer smaller than or equal to N.

Optionally, the reset control unit is configured to control, in a reset period, in response to a reset control signal outputted by the reset control signal output end, the control node to receive an initial signal outputted by the initial signal output end.

Optionally, the light-emission control unit includes a main light-emission control module and N secondary light-emission control modules, wherein the main light-emission control module is connected to the high level output end, the main light-emission control line and the first electrode of the driving transistor, and is configured to control, in the light-emission period, in response to the main light-emission control signal outputted by the main light-emission control line, the first electrode of the driving transistor to connect to the high level output end, to turn on the driving transistor; and an n^{th} secondary light-emission control module is connected to an n^{th} secondary light-emission control line, an n^{th} light-emission element and the second electrode of the driving transistor respectively, and is configured to control, in response to an n^{th} secondary light-emission control signal outputted by the n^{th} secondary light-emission control line, the n^{th} light-emission element to connect to the second electrode of the driving transistor to control the driving transistor to drive the n^{th} light-emission element to emit light.

Optionally, the main light-emission control module includes a light-emission control main transistor, a gate electrode of the light-emission control main transistor is connected to the main light-emission control line, a first electrode of the light-emission control main transistor is connected to the first electrode of the driving transistor, and a second electrode of the light-emission control main transistor is connected to the high level output end; and the n^{th} secondary light-emission control module includes an n^{th} light-emission control secondary transistor, a gate electrode of the n^{th} light-emission control secondary transistor is connected to the n^{th} secondary light-emission control line, a first electrode of the n^{th} light-emission control secondary transistor is connected to the second electrode of the driving transistor, and a second electrode of the n^{th} light-emission control secondary transistor is connected to the n^{th} light-emission element.

Optionally, the reset control unit includes a reset transistor, a gate electrode of the reset transistor is connected to the reset control signal output end, a first electrode of the reset transistor is connected to the initial signal output end, and a second electrode of the reset transistor is connected to the control node.

Optionally, the driving transistor is a P-type transistor, and a difference value between the initial signal outputted by the initial signal output end and the data voltage is less than a threshold voltage of the driving transistor; and the driving transistor is a N-type transistor, and the difference value between the initial signal outputted by the initial signal output end and the data voltage is greater than or equal to the threshold voltage of the driving transistor.

Optionally, the charging-discharging unit includes a storage capacitor, a first end of the storage capacitor is connected to the compensation control unit, and a second end of the storage capacitor is connected to the voltage output end.

Optionally, the compensation control unit includes: a first compensation control transistor, where a gate electrode of the first compensation control transistor is connected to the compensation control signal output end, a first electrode of the first compensation control transistor is connected to the data line, and a second electrode of the first compensation control transistor is connected to the first electrode of the driving transistor; and a second compensation control transistor, where a gate electrode of the second compensation control transistor is connected to the compensation control signal output end, a first electrode of the second compensation control transistor is connected to the first end of the charging-discharging unit, and second electrode of the second compensation control transistor is connected to the second electrode of the driving transistor.

In another aspect, the present disclosure further provides a method for driving a pixel driving circuit applied to the above pixel driving circuit, wherein each display period includes N display sub periods, each of the display sub periods includes a reset period, a compensating period and a light-emission period, N being a number of secondary light-emission control line in the pixel driving circuit; during an n^{th} display sub period in each display period, the method includes: a reset step: controlling, in the reset period, by the reset control unit, in response to a reset control signal, the control node to receive an initial signal; a compensating step: controlling, in the compensating period, by the compensation control unit, in response to the compensation control signal, the first electrode of the driving transistor to receive the data voltage on the data line, controlling the control node to be conducted to the second electrode of the driving transistor, and controlling the charging-discharging unit to charge or discharge until an electric potential of the first end of the charging-discharging unit is a sum value of the threshold voltage and the data voltage of the driving transistor; and a light-emission step: controlling, in the light-emission period, by the light-emission control unit, under the control of the n^{th} secondary light-emission control signal outputted by the n^{th} secondary light-emission control line, the first electrode of the driving transistor to connect to the high level output end, to turn on the driving transistor, and controlling, in response to the n^{th} secondary light-emission control signal outputted by the n^{th} secondary light-emission control line, the n^{th} light-emission element to connect to the second electrode of the driving transistor, to control the driving transistor to drive the n^{th} light-emission element to emit light, and make a gate-source voltage of the driving transistor to compensate the threshold voltage of the driving transistor, N is an integer greater than 1, and n is a positive integer less than or equal to N.

Optionally, in the case that the driving transistor is a P-type transistor, a difference value between the initial signal and the data voltage is less than the threshold voltage of the driving transistor; and the controlling, by the compensation control unit, the charging-discharging unit to charge or discharge until the electric potential of the first end of the charging-discharging unit is sum value of the threshold voltage and the data voltage of the driving transistor includes: controlling, by the compensation control unit, the charging-discharging unit to charge until the electric potential of the first end of the charging-discharging unit is the sum value of the threshold voltage and the data voltage of the driving transistor.

Optionally, in the case that the driving transistor is a N-type transistor, the difference value between the initial signal and the data voltage is greater than or equal to the threshold voltage of the driving transistor; and the controlling, by the compensation control unit, charging-discharging unit to charge or discharge until the electric potential of the first end of the charging-discharging unit is the sum value of the threshold voltage and the data voltage of the driving transistor includes: controlling, by the compensation control unit, the charging-discharging unit to discharge until the electric potential of the first end of the charging-discharging unit is the sum value of the threshold voltage and the data voltage of the driving transistor.

In yet another aspect, the present disclosure further provides a display device including the above pixel driving circuit.

Through the above technical solutions according to the present disclosure, advantageous effects of the present disclosure are as follows.

The pixel driving circuit according to the present disclosure realizes controlling of a plurality of pixels by one pixel driving circuit having compensation effect and function in a time-division manner, through a way of passive driving and scanning, to maximally compress a pattern-layout space of pixels of the back board, and ensure a high distributing effect of the size of PPI of the back board.

### BRIEF DESCRIPTION OF THE DRAWINGS

In order to illustrate technical solutions according to embodiments of the present disclosure more clearly, drawings to be used in the description of the embodiments of the present disclosure will be described briefly hereinafter. Apparently, the drawings described hereinafter are only some embodiments of the present disclosure, and other drawings may be obtained by those skilled in the art according to those drawings without creative work.

FIG. 1 is a schematic view showing a structure of a pixel driving circuit according to some embodiments of the present disclosure;

FIG. 2 is a schematic view showing a structure of a pixel driving circuit according to some embodiments of the present disclosure;

FIG. 3 is a signal time-sequence diagram of the pixel driving circuit during each working period according to some embodiments of the present disclosure;

FIG. 4 is a current flow diagram during a T1-1 reset period in a display sub period according to some embodiments of the present disclosure;

FIG. 5 is a current flow diagram during a T1-2 compensating period in a display sub period according to some embodiments of the present disclosure;

FIG. 6 is a current flow diagram during a T1-3 light-emission period in a display sub period according to some embodiments of the present disclosure; and

FIG. 7 is a flow chart of method for driving the pixel driving circuit according to some embodiments of the present disclosure.

### DETAILED DESCRIPTION

The technical solutions in embodiments of the present disclosure will be described hereinafter in a clear and complete manner in conjunction with appended drawings in the embodiments of the present disclosure, obviously, the described embodiments are merely a part of, rather than all of, the embodiments of the present disclosure, and based on these embodiments, a person skilled in the art may obtain the other embodiments, which also fall within the scope of the present disclosure.

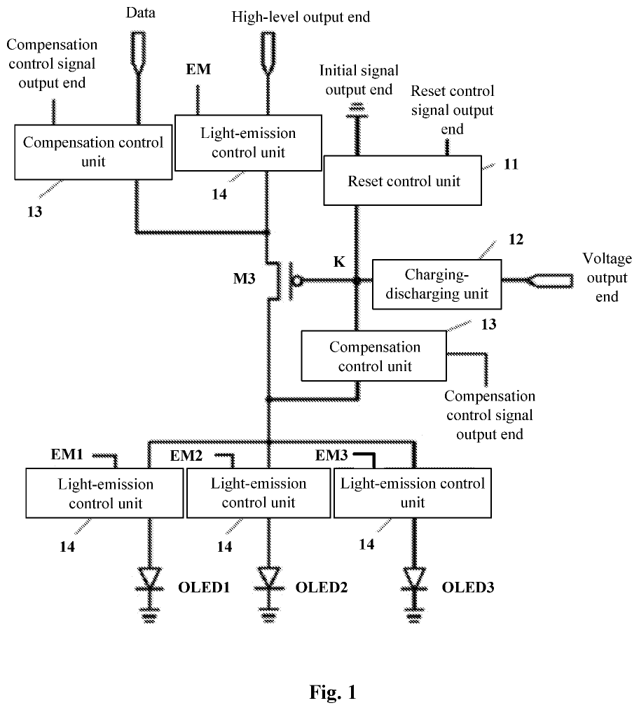

Referring to FIG. 1, the present disclosure provides in some embodiments a pixel driving circuit including a driving transistor M3, a reset control unit 11, a charging-discharging unit 12, a compensation control unit 13 and a light-emission control unit 14, which are described in detail below.

The reset control unit 11 is connected to a reset control signal output end Reset, an initial signal output end Vinit and a control node K respectively.

A gate electrode of the driving transistor M3 is connected to the control node K, a first electrode is connected to data line Data via the compensation control unit 13, and a second electrode of the driving transistor M3 is connected to a first end of the charging-discharging unit 12 via the compensation control unit 13.

A second end of the charging-discharging unit 12 is connected to a voltage output end Dd2.

The compensation control unit 13 is connected to a compensation control signal output end Gate, and is configured to: control, in a compensation period, in response to the compensation control signal outputted by the compensation control signal output end Gate, a first electrode of the driving transistor M3 to receive a data voltage Vdata on the data line Data, control the control node K to be connected to the second electrode of the driving transistor M3, and control the charging-discharging unit 12 to charge or discharge until an electric potential of the first end of the charging-discharging unit 12 is a sum value of a threshold voltage V^{th} and the data voltage Vdata of the driving transistor M3.

The light-emission control unit 14 is connected to a high level output end Dd1, a main light-emission control line EM, the first electrode of the driving transistor M3, the second electrode of the driving transistor M3, N secondary light-emission control lines (EM₁, EM₂, . . . , EM_{N}) and N light-emission elements (OLED₁, OLED₂, . . . , OLED_{N}) respectively, and is configured to control, in a light-emission period, in response to a main light-emission control signal outputted by the main light-emission control line EM, the first electrode of the driving transistor M3 to be connected to the high level output end Dd1, so as to control the driving transistor M3 to be turned on, and control, under controls of secondary light-emission control signals outputted by the N secondary light-emission control lines respectively, the N light-emission elements to be connected to the second electrode of the driving transistor M3 in a time-division manner, so as to control the driving transistor M3 to drive the N light-emission elements to emit light in the time-division manner, and make a gate-source voltage Vgs of the driving transistor M3 to compensate the threshold voltage V^{th} of the driving transistor M3. N is an integer greater than 1, n is a positive integer less than equal to N. Optionally, the light-emission element is an OLED.

It should be noted that, in FIG. 1, a number of the secondary light-emission control lines, i.e., N is 3, but the present disclosure is not limited thereto, and N may also be 10, 15 or 20 etc.

In FIG. 1, the light-emission element is an OLED, and the N light-emission elements are a plurality of light-emission elements in an identical row and different lines.

The pixel driving circuit according to the present disclosure realizes controlling of a plurality of pixels by one pixel driving circuit having compensation effect and function in a time-division manner, through a way of passive driving and scanning, to maximally compress a pattern-layout space of pixels of the back board, and ensure a high distributing effect of the size of PPI of the back board.

In some embodiments of the present disclosure, the reset control unit 11 is configured to control, in a reset period, in response to a reset control signal outputted by the reset control signal output end Reset, the control node K to receive an initial signal outputted by the initial signal output end Vinit.

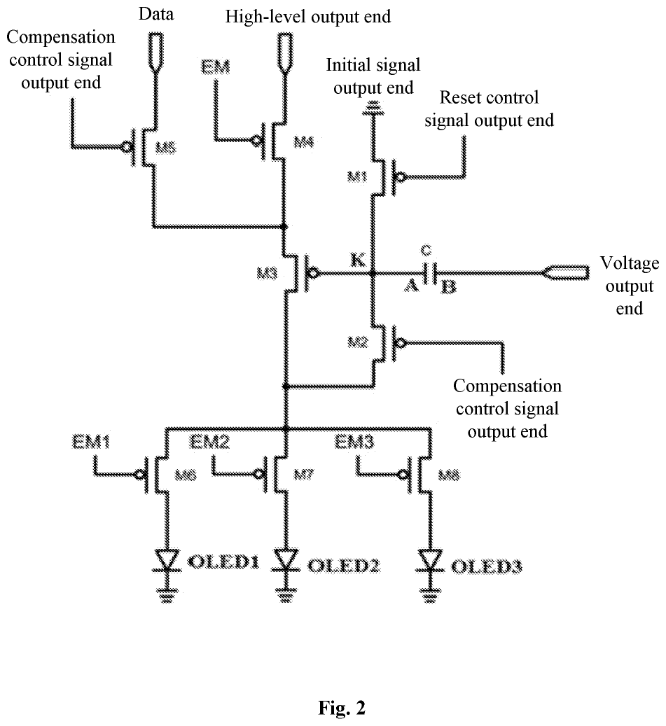

Referring to FIG. 2, in some embodiments of the present disclosure, the light-emission control unit 14 includes a main light-emission control module and N secondary light-emission control modules.

The main light-emission control module is connected to the high level output end Dd1, the main light-emission control line EM, and the first electrode of the driving transistor M3 respectively, and is configured to control, in the light-emission period, in response to the main light-emission control signal outputted by the main light-emission control line EM, the first electrode of the driving transistor M3 to be connected to the high level output end Dd1, so as to control the driving transistor M3 to be turned on.

An n^{th} secondary light-emission control module is connected to an n^{th} secondary light-emission control line EMn, an n^{th} light-emission element OLEDn and the second electrode of the driving transistor M3 respectively, and is configured to control, in response to an n^{th} secondary light-emission control signal outputted by the n^{th} secondary light-emission control line EMn, the n^{th} light-emission element OLEDn to be connected to the second electrode of the driving transistor M3 so as to control the driving transistor M3 to drive the n^{th} light-emission element OLEDn to emit light.

Specifically, in FIG. 2, the main light-emission control module includes a light-emission control main transistor M4, a gate electrode of the light-emission control main transistor M4 is connected to the main light-emission control line EM, a first electrode of the light-emission control main transistor M4 is connected to the first electrode of the driving transistor M3, and second electrode of the light-emission control main transistor M4 is connected to the high level output end Dd1.

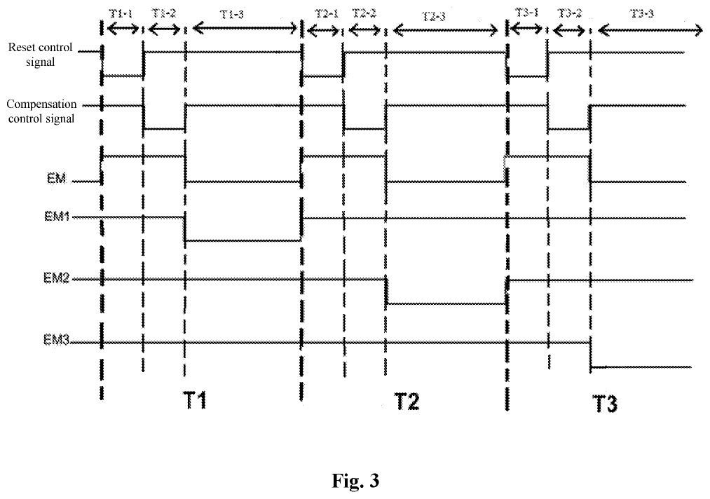

The n^{th} secondary light-emission control module includes an n^{th} light-emission control secondary transistor (e.g., M6, M7 or M8 in FIG. 3), a gate electrode of the n^{th} light-emission control secondary transistor is connected to the n^{th} secondary light-emission control line EMn (e.g., EM1, EM2 or EM3 in FIG. 3), a first electrode of the n^{th} light-emission control secondary transistor is connected to the second electrode of the driving transistor M3, and second electrode of the n^{th} light-emission control secondary transistor is connected to the n^{th} light-emission element OLEDn (e.g., OLED1, OLED2 or OLED3 in FIG. 3).

Still referring to FIG. 2, in some embodiments of the present disclosure, the reset control unit 11 includes a reset transistor M1, a gate electrode of the reset transistor M1 is connected to the reset control signal output end Reset, a first electrode of the reset transistor M1 is connected to the initial signal output end Vinit, and second electrode of the reset transistor M1 is connected to the control node K.

The charging-discharging unit 12 includes a storage capacitor C, a first end A of the storage capacitor C is connected to the compensation control unit 13 (a first electrode of a second compensation control transistor M2), and second end B of the storage capacitor C is connected to the voltage output end Dd2.

The compensation control unit 13 includes a first compensation control transistor M5 and the second compensation control transistor M2.

A gate electrode of the first compensation control transistor M5 is connected to the compensation control signal output end Gate, a first electrode of the first compensation control transistor M5 is connected to the data line Data, and a second electrode of the first compensation control transistor M5 is connected to the first electrode of the driving transistor M3.

A gate electrode of the second compensation control transistor M2 is connected to the compensation control signal output end Gate, a first electrode of the second compensation control transistor M2 is connected to the first end A of the storage capacitor C, and a second electrode of the second compensation control transistor M2 is connected to the second electrode of the driving transistor M3.

It should be noted that, the transistors employed in embodiments of the present disclosure may be thin film transistors or field-effect transistors or other components having identical characteristics. In some embodiments of the present disclosure, in order to differentiate two electrodes except the gate electrode of the transistor, where a first electrode may be a source electrode or a drain electrode, and a second electrode may be the drain electrode or the source electrode. In addition, according to characteristics of transistors, transistors may be divided into transistors of n-type or transistors of p-type, in the driving circuit according to some embodiments of the present disclosure, all transistors may be transistors of n-type or transistor s of p-type, which will not be limited by the present disclosure.

In the pixel driving circuit according to some embodiments of the present disclosure, in order to ensure that the driving transistor is smoothly turned on in the compensating period, in the case that the driving transistor M3 is a P-type transistor, a difference value between the initial signal outputted by the initial signal output end Vinit and the data voltage Vdata is less than the threshold voltage V^{th} of the driving transistor M3; and in the case that the driving transistor M3 is a N-type transistor, the difference value between the initial signal outputted by the initial signal output end Vinit and the data voltage Vdata is greater than or equal to the threshold voltage V^{th} of the driving transistor M3.

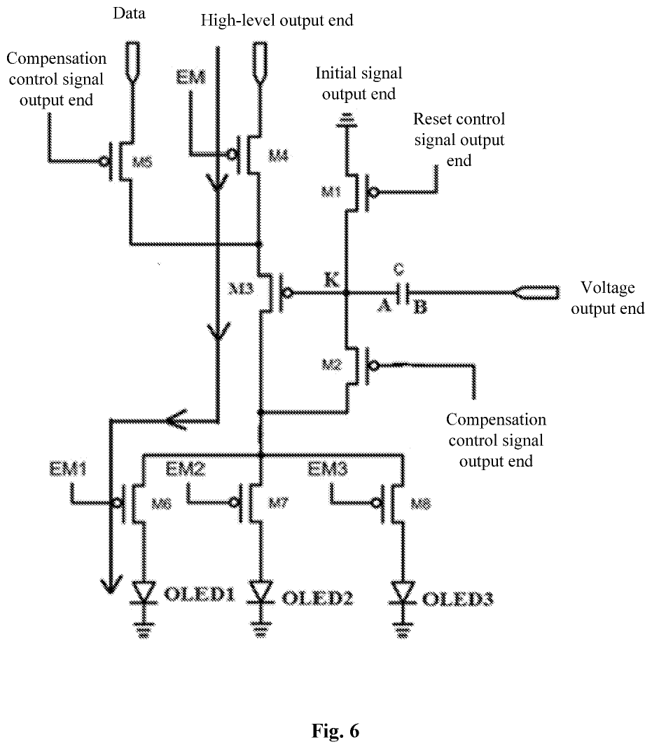

A working process of the pixel driving circuit will be described hereinafter in conjunction with FIG. 2˜FIG. 6 by taking a case where all transistors in the pixel driving circuit according to some embodiments of the present disclosure are transistors of p-type as an example.

FIG. 3 provides time sequence diagram for compensation controlling of three pixels (T1, T2 and T3), and description will be made by taking a compensation driving time-sequence of one pixel of the three pixels, i.e., T1, as an example. The T1 time-sequence corresponds to light-emission control secondary transistor M6 in FIG. 2. The specific process is as follows.

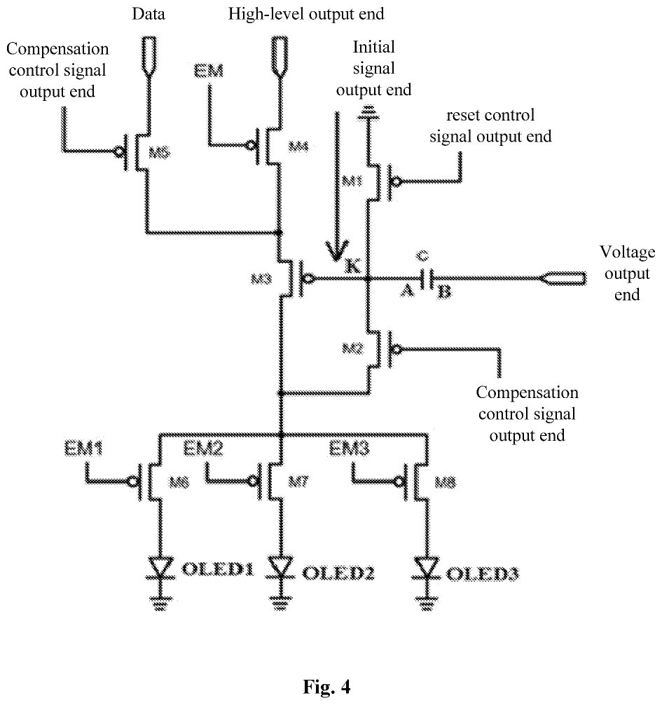

T1-1: a reset period, in which Reset outputs a low-level, Gate, EM, EM1, EM2 and EM3 each outputs a high level, as this timing, referring to FIG. 4, M1 is turned on, M2˜M8 are turned off, an electric potential of node K is reset to an initial signal outputted by Vinit;

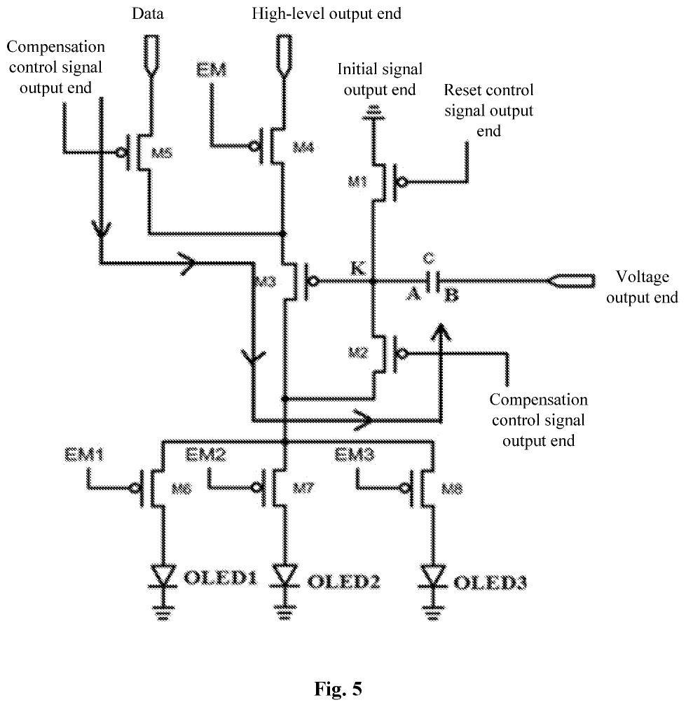

T1-2: compensating period, in which Gate outputs the low-level, Reset, EM, EM1, EM2 and EM3 each outputs the high level, at this timing, referring to FIG. 5, M5, M3 and M2 are turned on, M1, M4 and M6˜M8 are turned off, the first electrode of M3 is controlled to receive Vdata, node K is conducted to the second electrode of M3, and C is charged until an electric potential Va of A equals to a sum value of V^{th} and Vdata, at this timing, an electric potential Vb of B is Vdd2; and

T1-3: a light-emission period, in which EM and EM1 each outputs the low-level, Reset, Gate, EM2 and EM3 each outputs the high level, at this timing, referring to FIG. 6, M4, M3 and M6 are turned on, M1, M2, M5, M7 and M8 are turned off, the first electrode of control M3 is controlled to receive a high level Vdd1, OLED1 is controlled to be connected to the second electrode of M3, so as to control M3 to drive OLED1 to emit light.

A current I_{OLED} flowing through the OLED may be calculated from a saturation current formula of TFT of I_{OLED}=K(Vgs−Vth)²=K(Vth+Vdata−Vdd1−Vth)²=K(Vdata−Vdd1)².

It can be seen from the above formula that, a working current I_{OLED} is only related to the Vdata, and is independent of the V^{th} already. In this way, the pixel compensating circuit according to embodiments of the present disclosure thoroughly resolves the problem of drift of threshold voltage (Vth) of the driving TFT due to a long manufacture procedure of the process and long operation, eliminates the impact thereof with respect to the I_{OLED}, and ensures a normal work of the OLED.

On the basis of the time-sequence diagram shown in FIG. 3, after completing time-sequence T1, with reference to time-sequence T1, the time-sequence T2 (including a reset period T2-1, a compensating period T2-2 and a light-emission period T2-3) and the time-sequence T3 (including a reset period T3-1, a compensating period T3-2 and a light-emission period T3-3) may be smoothly completed, so as to complete a compensation light-emission procedure in sequence. Meanwhile, such a way similar to driving of PMOLED has a compensation function, and the way of sequential scanning ensures a uniformity of display, and realizes the object of time-division controlling of the plurality of pixels by one pixel driving circuit.

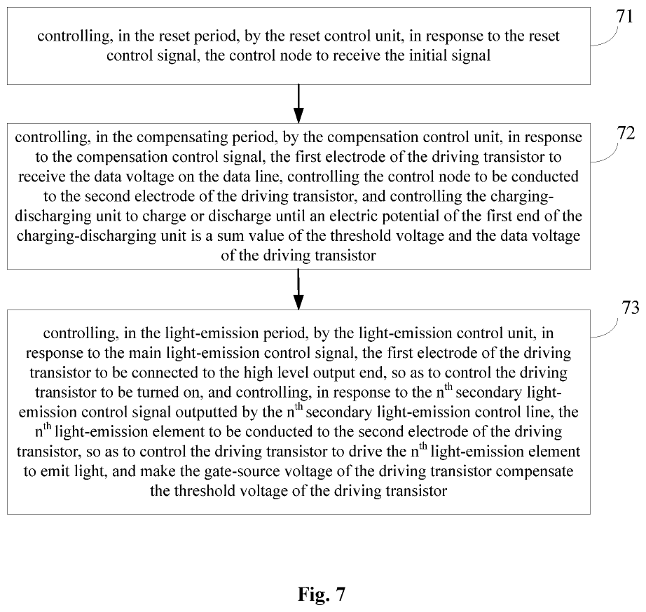

Referring to FIG. 7, the present disclosure further provides in some embodiments a method for driving a pixel driving circuit, applied to the above pixel driving circuit, each display period includes N display sub periods, and each of the display sub periods includes a reset period, a compensating period and a light-emission period, N being a number of secondary light-emission control line in the pixel driving circuit.

During an n^{th} display sub period in each display period, the method includes:

a reset step 71, controlling, in the reset period, by the reset control unit, in response to the reset control signal, the control node to receive the initial signal;

a compensating step 72: controlling, in the compensating period, by the compensation control unit, in response to the compensation control signal, the first electrode of the driving transistor to receive the data voltage on the data line, controlling the control node to be conducted to the second electrode of the driving transistor, and controlling the charging-discharging unit to charge or discharge until an electric potential of the first end of the charging-discharging unit is a sum value of the threshold voltage and the data voltage of the driving transistor; and

a light-emission step 73: controlling, in the light-emission period, by the light-emission control unit, in response to the main light-emission control signal, the first electrode of the driving transistor to be connected to the high level output end, so as to control the driving transistor to be turned on, and controlling, in response to the n^{th} secondary light-emission control signal outputted by the n^{th} secondary light-emission control line, the n^{th} light-emission element to be conducted to the second electrode of the driving transistor, so as to control the driving transistor to drive the n^{th} light-emission element to emit light, and make the gate-source voltage of the driving transistor compensate the threshold voltage of the driving transistor, N being an integer greater than 1, and n being a positive integer less than or equal to N.

In some embodiments of the present disclosure, in the case that the driving transistor is a P-type transistor, a difference value between the initial signal and the data voltage is less than the threshold voltage of the driving transistor; and

controlling, by the compensation control unit, the charging-discharging unit to charger or discharge until the electric potential of the first end of the charging-discharging unit is the sum value of the threshold voltage and the data voltage of the driving transistor includes: controlling, by the compensation control unit, the charging-discharging unit to charge until the electric potential of the first end of the charging-discharging unit is the sum value of the threshold voltage and the data voltage of the driving transistor.

In some embodiments of the present disclosure, in the case that the driving transistor is a N-type transistor, the difference value between the initial signal and the data voltage is greater than or equal to the threshold voltage of the driving transistor; and

controlling, by the compensation control unit, the charging-discharging unit to charge or discharge until the electric potential of the first end of the charging-discharging unit is the sum value of the threshold voltage and the data voltage of the driving transistor includes: controlling, by the compensation control unit, the charging-discharging unit to discharge until the electric potential of the first end of the charging-discharging unit is the sum value of the threshold voltage and the data voltage of the driving transistor.

The present disclosure further provides in some embodiments a display device including the above pixel driving circuit.

Persons of ordinary skill in the art should understand that all or a part of the steps of the foregoing method embodiments may be implemented by a program instructing relevant hardware. The program may be stored in a computer readable storage medium. When the program is executed, the steps of the foregoing method embodiments are performed. The foregoing storage medium may be various mediums capable of storing program codes, such as a ROM, a RAM, a magnetic disk, or a compact disk, and so on.

The above are merely the optional embodiments of the present disclosure. It should be noted that, a person skilled in the art may make improvements and modifications without departing from the principle of the present disclosure, and these improvements and modifications shall also fall within the scope of the present disclosure.

1. A pixel driving circuit, comprising a driving transistor, a reset control unit, a charging-discharging unit, a compensation control unit and a light-emission control unit, wherein
the reset control unit is connected to a reset control signal output end, an initial signal output end and a control node;
a gate electrode of the driving transistor is connected to the control node, a first electrode of the driving transistor is connected to a data line via the compensation control unit, and a second electrode of the driving transistor is connected to a first end of the charging-discharging unit via the compensation control unit;
a second end of the charging-discharging unit is connected to a voltage output end;
the compensation control unit is connected to a compensation control signal output end, and is configured to control, in a compensating period, in response to a compensation control signal outputted by the compensation control signal output end, the first electrode of the driving transistor to receive a data voltage on the data line and control the control node to be conducted to the second electrode of the driving transistor; and
the light-emission control unit is connected to a high level output end, a main light-emission control line, the first electrode of the driving transistor, the second electrode of the driving transistor, N secondary light-emission control lines and N light-emission elements, and is configured to control, in a light-emission period, in response to a main light-emission control signal outputted by the main light-emission control line, the first electrode of the driving transistor to connect to the high level output end, to turn on the driving transistor, and control, in response to secondary light-emission control signals outputted by the N secondary light-emission control lines respectively, the N light-emission elements to connect to the second electrode of the driving transistor in a time-division manner, wherein N is an integer greater than 1, and n is a positive integer smaller than or equal to N.

2. The pixel driving circuit according to claim 1, wherein the reset control unit is configured to control, in a reset period, in response to a reset control signal outputted by the reset control signal output end, the control node to receive an initial signal outputted by the initial signal output end.

3. The pixel driving circuit according to claim 1, wherein the light-emission control unit comprises a main light-emission control module and N secondary light-emission control modules, wherein
the main light-emission control module is connected to the high level output end, the main light-emission control line and the first electrode of the driving transistor, and is configured to control, in the light-emission period, in response to the main light-emission control signal outputted by the main light-emission control line, the first electrode of the driving transistor to connect to the high level output end, to turn on the driving transistor; and
an n^{th} secondary light-emission control module is connected to an n^{th} secondary light-emission control line, an n^{th} light-emission element and the second electrode of the driving transistor, and is configured to control, in response to an n^{th} secondary light-emission control signal outputted by the n^{th} secondary light-emission control line, the n^{th} light-emission element to connect to the second electrode of the driving transistor, to control the driving transistor to drive the n^{th} light-emission element to emit light.

4. The pixel driving circuit according to claim 3, wherein the main light-emission control module comprises a light-emission control main transistor, a gate electrode of the light-emission control main transistor is connected to the main light-emission control line, a first electrode of the light-emission control main transistor is connected to the first electrode of the driving transistor, and a second electrode of the light-emission control main transistor is connected to the high level output end; and
the n^{th} secondary light-emission control module comprises an n^{th} light-emission control secondary transistor, a gate electrode of the n^{th} light-emission control secondary transistor is connected to the n^{th} secondary light-emission control line, a first electrode of the n^{th} light-emission control secondary transistor is connected to the second electrode of the driving transistor, and a second electrode of the n^{th} light-emission control secondary transistor is connected to the n^{th} light-emission element.

5. The pixel driving circuit according to claim 2, wherein the reset control unit comprises a reset transistor, a gate electrode of the reset transistor is connected to the reset control signal output end, a first electrode of the reset transistor is connected to the initial signal output end, and a second electrode of the reset transistor is connected to the control node.

6. The pixel driving circuit according to claim 5, wherein the driving transistor is a P-type transistor, and a difference value between the initial signal outputted by the initial signal output end and the data voltage is less than a threshold voltage of the driving transistor.

7. The pixel driving circuit according to claim 5, wherein the driving transistor is a N-type transistor, and the difference value between the initial signal outputted by the initial signal output end and the data voltage is greater than or equal to a threshold voltage of the driving transistor.

8. The pixel driving circuit according to claim 1, wherein the charging-discharging unit comprises a storage capacitor, a first end of the storage capacitor is connected to the compensation control unit, and a second end of the storage capacitor is connected to the voltage output end.

9. The pixel driving circuit according to claim 1, wherein the compensation control unit comprises:
a first compensation control transistor, wherein a gate electrode of the first compensation control transistor is connected to the compensation control signal output end, a first electrode of the first compensation control transistor is connected to the data line, and a second electrode of the first compensation control transistor is connected to the first electrode of the driving transistor; and
a second compensation control transistor, wherein a gate electrode of the second compensation control transistor is connected to the compensation control signal output end, a first electrode of the second compensation control transistor is connected to the first end of the charging-discharging unit, and second electrode of the second compensation control transistor is connected to the second electrode of the driving transistor.

10. A method for driving the pixel driving circuit according to claim 1, wherein each display period comprises N display sub periods, each of the display sub periods comprises a reset period, a compensating period and a light-emission period, wherein N is a number of the secondary light-emission control lines in the pixel driving circuit;
during an n^{th} display sub period in each display period, the method comprises:
a reset step: controlling, in the reset period, by the reset control unit, in response to a reset control signal, the control node to receive an initial signal;
a compensating step: controlling, in the compensating period, by the compensation control unit, in response to a compensation control signal, the first electrode of the driving transistor to receive a data voltage on the data line, controlling the control node to be conducted to the second electrode of the driving transistor, and controlling the charging-discharging unit to charge or discharge until an electric potential of the first end of the charging-discharging unit is a sum value of a threshold voltage and the data voltage of the driving transistor; and
a light-emission step: controlling, in the light-emission period, by the light-emission control unit, in response to a main light-emission control signal, the first electrode of the driving transistor to connect to the high level output end, to turn on the driving transistor, and controlling, in response to an n^{th} secondary light-emission control signal outputted by the n^{th} secondary light-emission control line, the n^{th} light-emission element to connect to the second electrode of the driving transistor, to control the driving transistor to drive the n^{th} light-emission element to emit light, and make a gate-source voltage of the driving transistor to compensate the threshold voltage of the driving transistor, wherein N is an integer greater than 1, and n is a positive integer less than or equal to N.

11. The method according to claim 10, wherein the driving transistor is a P-type transistor, and a difference value between the initial signal and the data voltage is less than the threshold voltage of the driving transistor; and
the controlling, by the compensation control unit, the charging-discharging unit to charge or discharge until the electric potential of the first end of the charging-discharging unit is the sum value of the threshold voltage and the data voltage of the driving transistor comprises: controlling, by the compensation control unit, the charging-discharging unit to charge until the electric potential of the first end of the charging-discharging unit is the sum value of the threshold voltage and the data voltage of the driving transistor.

12. The method according to claim 10, wherein the driving transistor is a N-type transistor, the difference value between the initial signal and the data voltage is greater than or equal to the threshold voltage of the driving transistor; and
the controlling, by the compensation control unit, the charging-discharging unit to charge or discharge until the electric potential of the first end of the charging-discharging unit is the sum value of the threshold voltage and the data voltage of the driving transistor comprises: controlling, by the compensation control unit, the charging-discharging unit to discharge until the electric potential of the first end of the charging-discharging unit is the sum value of the threshold voltage and the data voltage of the driving transistor.

13. A display device comprising the pixel driving circuit according claim 1.

14. A display device comprising the pixel driving circuit according to claim 2.

15. A display device comprising the pixel driving circuit according to claim 3.

16. A display device comprising the pixel driving circuit according to claim 4.

17. A display device comprising the pixel driving circuit according to claim 5.

18. A display device comprising the pixel driving circuit according to claim 6.

19. A display device comprising the pixel driving circuit according to claim 7.

20. A display device comprising the pixel driving circuit according to claim 8.
